(19) United States
(12) Patent Application Publication
(10) Pub. No.: US 2012/0070981 A1
(43) Pub. Date: Mar. 22, 2012

(54) ATOMIC LAYER DEPOSITION OF A COPPER-CONTAINING SEED LAYER

(76) Inventors: Scott B. Clendenning, Portland, OR (US); James M. Blackwell, Portland, OR (US); Patricio Romero, Portland, OR (US); John Plombon, Portland, OR (US)

(21) Appl. No.: 12/885,097

(22) Filed: Sep. 17, 2010

(51) Int. Cl. H01L 21/3205

(52) U.S. Cl. 438/653; 438/652; 257/E21.295

(57) ABSTRACT

The present disclosure relates to the field of microelectronic device fabrication and, more particularly, to the formation of copper-containing seed layers for the fabrication of interconnects in integrated circuits. The copper-containing seed layers may be formed in an atomic layer deposition process with a copper pre-cursor and organometallic co-reagent.

### BACKGROUND

Embodiments of the present description generally relate to the field of microelectronic device fabrication and, more particularly, to the formation of seed layers for the fabrication of interconnects in integrated circuits.

### BRIEF DESCRIPTION OF THE DRAWINGS

The subject matter of the present disclosure is particularly pointed out and distinctly claimed in the concluding portion of the specification. The foregoing and other features of the present disclosure will become more fully apparent from the following description and appended claims, taken in conjunction with the accompanying drawings. It is understood that the accompanying drawings depict only several embodiments in accordance with the present disclosure and are, therefore, not to be considered limiting of its scope. The disclosure will be described with additional specificity and detail through use of the accompanying drawings, such that the advantages of the present disclosure can be more readily ascertained, in which:

FIG. 1 illustrates a side cross-sectional view of a opening formed in a dielectric material layer.

FIG. 2 illustrates a side cross-sectional view of the opening of FIG. 1 with a copper-containing seed layer therein.

FIG. 3 is a flow diagram of one embodiment of a process of forming a copper-containing seed layer.

FIG. 4 is a simplified chemical reaction flow diagram of one embodiment of a copper-containing seed layer.

FIG. 5 illustrates a side cross-sectional view of depositing a conductive material on the copper-containing seed layer of FIG. 2.

FIG. 6 illustrates a side cross-sectional view of forming an interconnect from the structure of FIG. 5.

FIG. 7 illustrates a side-cross sectional view of a barrier layer formed between the dielectric material layer and the copper-containing seed layer.

FIGS. 8-14 illustrate side cross-sectional views of forming a barrier layer from the metal alloyed with the copper in the copper-containing seed layer.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. It is to be understood that the various embodiments, although different, are not necessarily mutually exclusive. For example, a particular feature, structure, or characteristic described herein, in connection with one embodiment, may be implemented within other embodiments without departing from the spirit and scope of the claimed subject matter. In addition, it is to be understood that the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled. In the drawings, like numerals refer to the same or similar elements or functionality throughout the several views, and that elements depicted therein are not necessarily to scale with one another, rather individual elements may be enlarged or reduced in order to more easily comprehend the elements in the context of the present description.

Embodiments of the present description generally relate to the field of microelectronic device fabrication and, more particularly, to the formation of copper-containing seed layers for the fabrication of interconnects in integrated circuits. The copper-containing seed layer may be formed in an atomic layer deposition process with a copper pre-cursor and organometallic co-reagent.

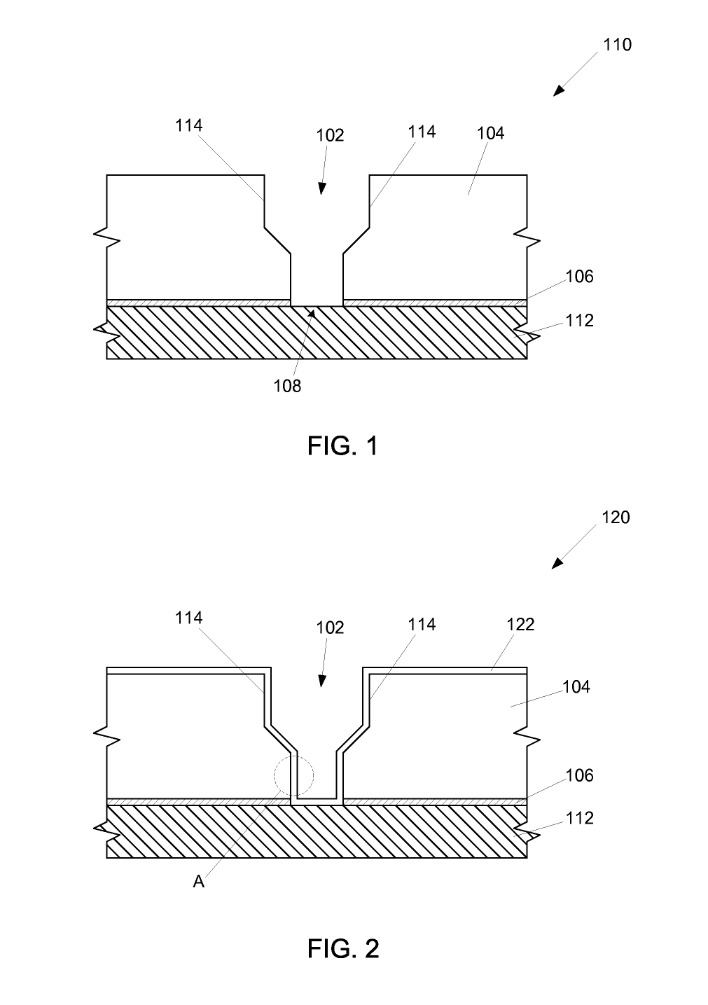

FIGS. 1-14 illustrate cross-sectional views and flow diagrams of embodiments of a processes for forming a seed layer in the fabrication of an interconnect, such as a back-end-of-line (BEOL) interconnect. As shown in FIG. 1, an opening 102 may be formed through a dielectric material layer 104 and a first barrier layer 106 to expose at least a portion 108 of a substrate 112, wherein the opening 102 includes at least one sidewall 114, thereby forming a first intermediate structure 110. It is understood that the opening 102 may be a via, a trench, or a combination thereof, such as in a dual damascene opening as shown, as will be understood to those skilled in the art.

The substrate 112 may be a silicon-containing material wherein the exposed substrate portion 108 corresponds to a circuit component (not shown) formed in the substrate 112 or may be a conductive trace, which may be made of copper, aluminum, silver, gold, and the like, as well as alloys thereof. In one embodiment, the substrate 112 is a copper trace. The first barrier layer 106 may be an etch stop layer, such as silicon carbide, silicon nitride, silicon oxycarbide, silicon oxycarbonitride, and the like. The dielectric material layer 104 may include, but is not limited to, interlayer dielectrics such as silicon dioxide, carbon-doped silicon dioxides, polymer-based materials (e.g. fluorocarbons, hydrocarbons), and low-k, carbon rich dielectrics.

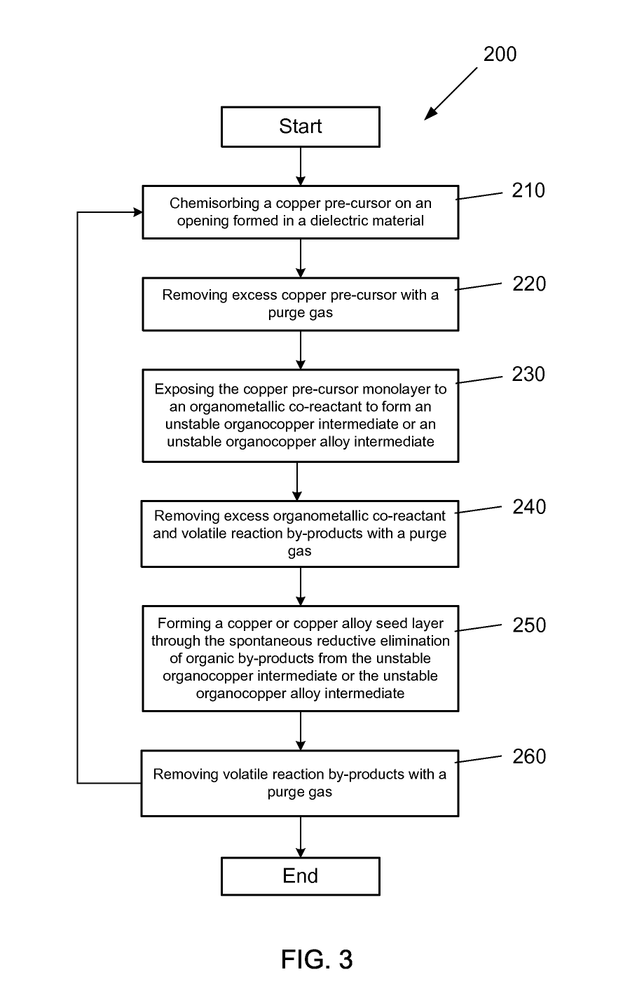

As shown in FIG. 2, a copper-containing seed layer 122 may be deposited over the dielectric material layer 104 and into the opening 102 to contact the substrate 112, thereby forming a second intermediate structure 120. The copper-containing seed layer 122 may be formed with an atomic layer deposition (ALD) process. The ALD process is related to the process of chemical vapor deposition (CVD), in that the metal source is a volatile metal complex. However, deposition is achieved not by thermal decomposition of a metal complex on a heated substrate surface (CVD), but by repeated alternating surface controlled reactions between a metal pre-cursor and a co-reagent, at least one of which is adsorbed on the substrate surface during the nucleation process to initiate ALD film growth. In a typical ALD process, the metal pre-cursor is chemisorbed on the film surface in a self-limiting fashion (at a temperature at which CVD does not occur), and any excess pre-cursor and volatile byproducts are removed with an inert gas purge. Vapors of a volatile co-reagent are then introduced to the surface, and react with the chemisorbed metal pre-cursor to deposit the desired material (e.g., a metal film), affect the release of volatile byproducts, and create a suitable surface functionalization to allow reaction in the next metal pre-cursor vapor exposure. The surface reaction with the co-reagent is also self-limiting and excess co-reagent and volatile byproducts are removed with an inert gas purge. Due to the self-limiting nature of the surface reactions, the ALD process is characterized by highly conformal and uniform, self-limited film growth which allows for highly uniform, ultrathin (e.g. less than 50 Å) film.

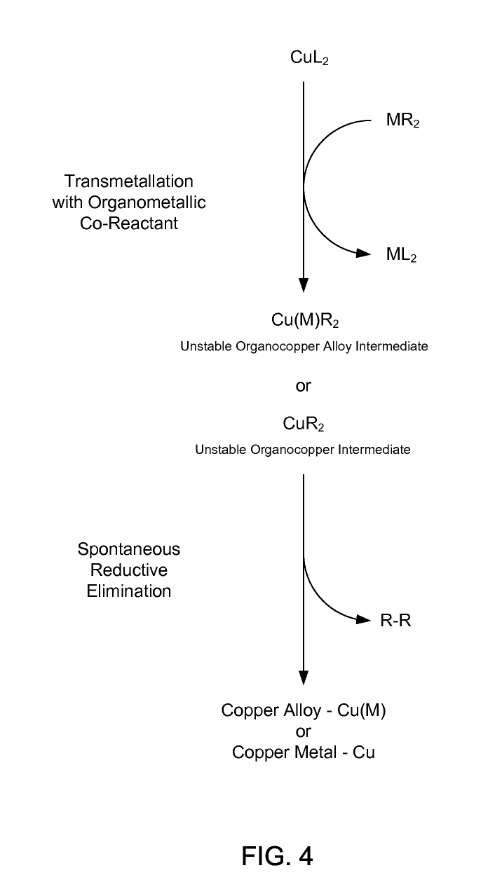

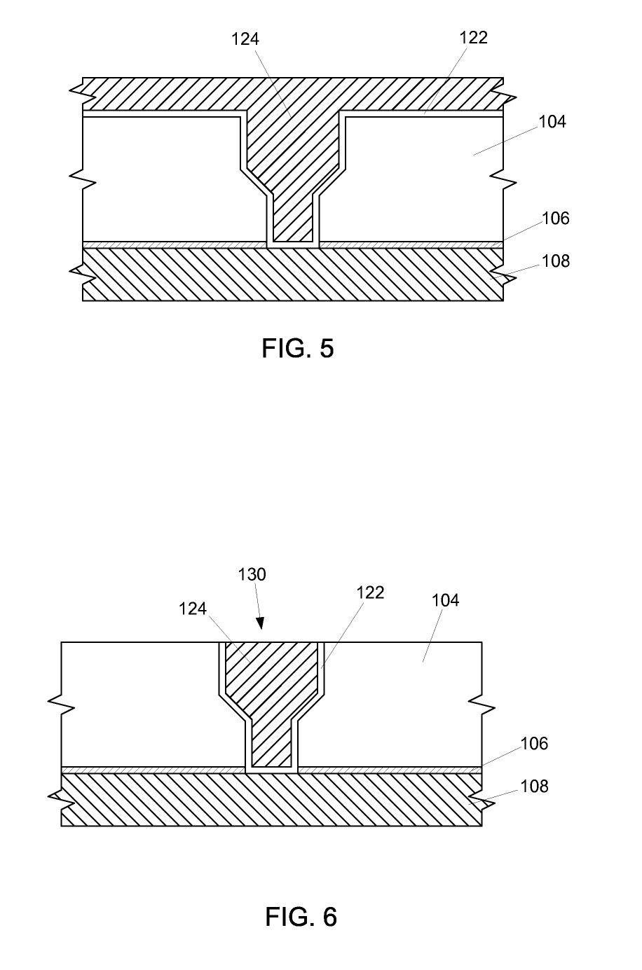

FIGS. 3 and 4 illustrate an embodiment of an ALD process 200 of the present description. In step 210, a copper pre-cursor may be introduced to the first intermediate structure 110 of FIG. 1 to form a monolayer thereon (shown as CuL₂ in FIG. 4). The copper pre-cursor may be any appropriate pre-cursor, including but not limited to homoleptic (i.e. all ligands (functional groups) are identical) or heteroleptic copper(I) and copper(II) compounds. In one embodiment, the copper pre-cursor is a copper(II) compound, as they are generally less air and moisture sensitive than copper(I) pre-cursors. The copper(II) compounds may include, but are not limited to the compounds illustrated in Table 1. In Table 1, R₁, R₂, R₃, and R₄ may represent a generic organic substituent or hydrogen. The substitution pattern may arise from any combination, where R₁=R₂=R₃=R₄, or where R₁≠R₂≠R₃≠R₄, or any permissible combination therebetween.

TABLE 1

| | |
|---|---|
| 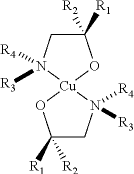 | 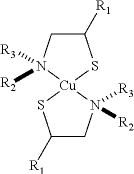 |
| 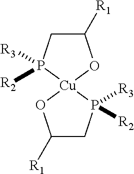 | 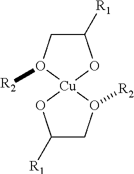 |
| 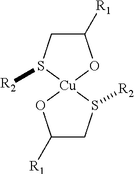 | 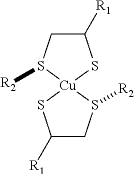 |
| 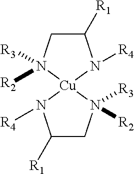 | 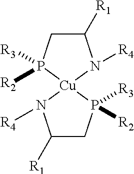 |
| 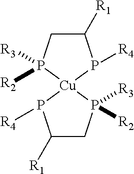 | 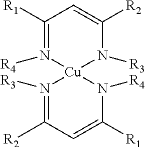 |

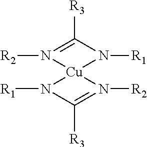

Excess copper pre-cursor may then be removed with a purge gas, as shown in step 220. As shown in step 230, the monolayer may be exposed to an organometallic co-reagent (shown as MR₂ in FIG. 4) to form an unstable organocopper intermediate or an unstable organocopper alloy intermediate (shown as CuR₂ or Cu(M)R₂, respectively, in FIG. 4). As will be understood to those skilled in the art, whether an organocopper intermediate or a organocopper alloy intermediate is formed will depend on the copper pre-cursor selected, the organometallic co-reagent selected, and/or the operating parameters of the deposition (e.g., temperature, pressure, and the like).

As shown in step 240 for FIG. 3, any excess organometallic co-reagent and volatile reaction by-products (shown as ML₂ in FIG. 4) may be removed with an inert gas purge.

The organometallic co-reagent may be any appropriate co-reagent, including but not limited to homoleptic (i.e. all ligands (functional groups) are identical) or heteroleptic organomanganese, organoaluminum, organomagnesium, organozinc, or organotin compounds. The organometallic compounds may include, but are not limited to, alkyl groups, alkenyl groups, alkynyl groups, and the like. The co-reagent compounds may include, but are not limited to the compounds illustrated in Table 2. In Table 2, M may be zinc, magnesium, or manganese and R₁, R₂, R₃, and R₄ may represent a generic organic substituent or hydrogen. The substitution pattern may arise from any combination, where R₁=R₂=R₃=R₄, or where R₁≠R₂≠R₃≠R₄, or any permissible combination therebetween.

TABLE 2

| | |
|---|---|
| 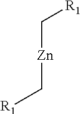 | 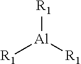 |
| 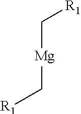 | 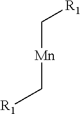 |
| 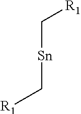 | 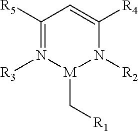 |
| 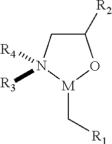 | 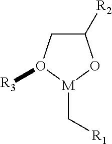 |
| 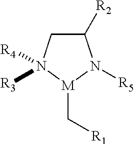 | 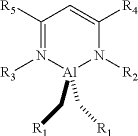 |
| 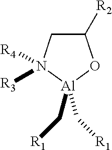 | 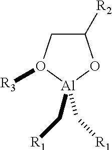 |
| 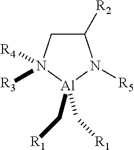 | 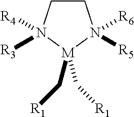 |
| 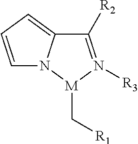 | 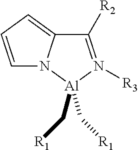 |

As shown in step 250 of FIG. 3, the unstable organocopper intermediate or the unstable organocopper alloy intermediate (shown as CuR₂ or Cu(M)R₂, respectively, in FIG. 4) spontaneously undergoes a reductive elimination of organic by-products, which forms a copper Cu or a copper alloy Cu(M) seed layer, respectively, (see copper-containing seed layer 122 of FIG. 2). The excess co-reagent and volatile reaction by-products (shown as R—R in FIG. 4) may be removed with an inert gas purge, as shown in step 260 of FIG. 3.

In one embodiment, where the copper-containing seed layer 122 is formed from the unstable organocopper intermediate, the copper-containing seed layer 122 may have a total combined impurity content of less than about 1% (atomic). In one embodiment, where the copper-containing seed layer 122 is formed form the unstable organocopper alloy intermediate, the concentration of alloy metal (e.g., manganese, aluminum, magnesium, zinc, or tin) may be between about 1% and 5% atomic.

It is understood that steps 210 through 260 may be repeated in the same sequence in multiple cycles to build a desired thickness for the copper-containing seed layer 122 (see FIG. 2). It is understood the multiple cycles need not be of the same copper pre-cursor and/or the same organometallic co-reagent. As a general example, one could execute four cycles of a copper pre-cursor reacting with the first organometellic co-reagent that forms four seed layers of substantially pure copper followed by one cycle of the same copper pre-cursor reacting with second organometallic co-reagent that forms a copper alloy seed layer. Of course, one could form any number of copper and copper alloy seed layers in any combination using any number and combination of copper pre-cursors and organometallic co-reagents.

It is also understood that the first intermediate substrate 110 of FIG. 1 may be activated prior to the ALD deposition by exposure to organic or inorganic atomic layer deposition nucleation promoting substance(s) in solution or the vapor phase, or may be activated through exposure to electromagnetic radiation or a plasma, as will be understood to those skilled in the art.

As illustrated in FIG. 2, the atomic layer deposition of the copper-containing seed layer can be done directly on exposed underlying metal layers to enable “bottomless” vias for decreased interconnect resistance.

In one embodiment, the copper pre-cursor (shown as CuL₂ in FIG. 4) may be bis(dimethylamino-2-propoxide)copper(II) and the organometallic co-reagent (shown as MR₂ in FIG. 4) may be a triethylaluminum organometallic co-reagent. When the process, as discussed above, is performed at about 100° C. and deposited on a carbon-doped silicon dioxide dielectric, the copper-containing seed layer 122 of about 96% (atomic) of copper, about 2% (atomic) carbon, about 2% (atomic) oxygen, having a resistivity of about 2.7 μQ·cm, may be formed.

The use of the ALD process of the present description to form the copper-containing seed layer 122 allows a controlled thin film deposition and, by its nature, is highly uniform and conformal over three-dimensional structures, and, thus, may circumvent the limitations of current physical vapor deposition copper seed layer formation processes caused by the directional nature of physical vapor deposition, which may result in difficulties in uniformly depositing material at the bottom and on the sidewalls of high aspect ratio features, as will be understood to those skilled in the art. In one embodiment, the atomic layer deposition may be performed at a relatively low temperature between about 20° C. and 150° C. Having low substrate temperatures and the lack of plasma co-reagents (as are necessary in physical vapor deposition methods) may enable the formation of more conformal seed layers and may eliminate plasma damage to dielectric layers, particularly low-k dielectrics.

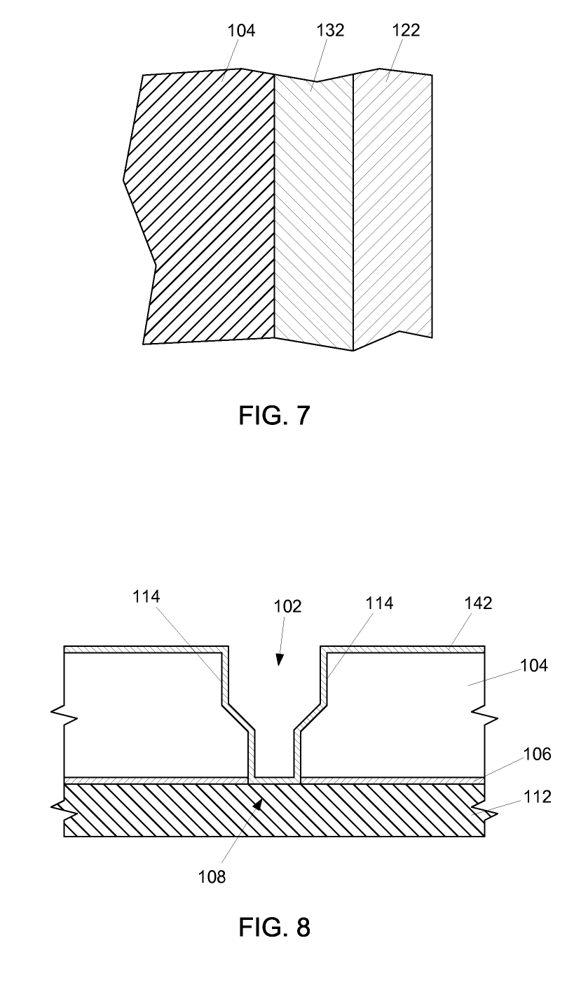

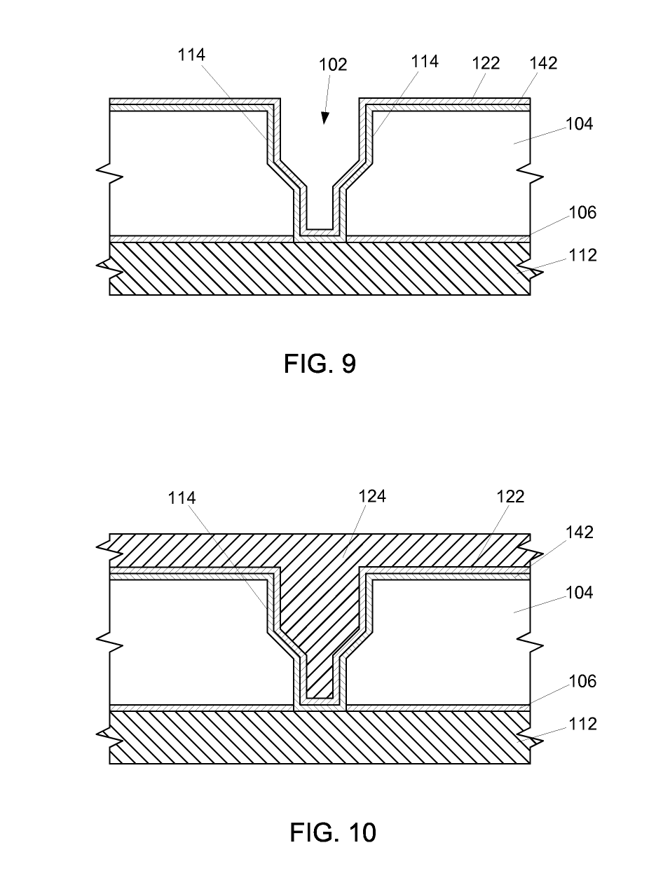

As shown in FIG. 5, the opening 102 may be filled with a conductive material 124. The conductive material 124 may be any appropriate conductive material, including but not limited to copper, aluminum, silver, gold, cobalt, tungsten, and the like, as well as alloys thereof. In one embodiment, the conductive material 124 is copper or an alloy thereof. The conductive material 124 may be deposited by any technique known in the art, including but not limited to electroless plating and electroplating. As shown in FIG. 6, a portion of the conductive material 124 overlying (not within the opening 102 (see FIG. 2)) the dielectric material layer 104 may be removed, such as by chemical mechanical polishing, to form an interconnect 130.

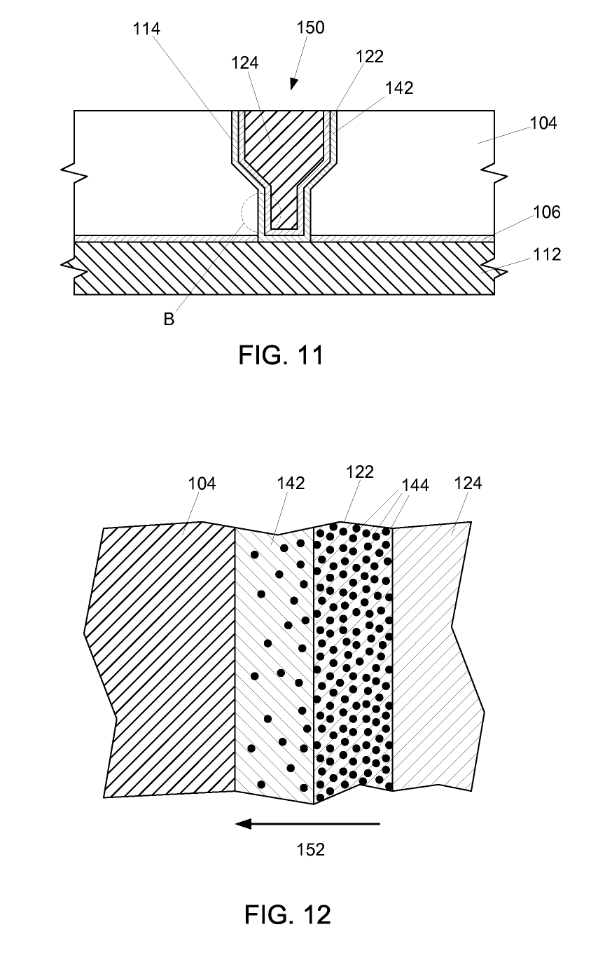

In an embodiment of the present description, an interconnect barrier layer 132 may be formed between the copper-containing seed layer 122 and the dielectric material layer 104, as shown in FIG. 7 (inset A of FIG. 2). In one embodiment, the interconnect barrier layer 132 may be formed through reaction of the copper-containing seed layer 122 with the dielectric layer 104 and may or may not require a thermal anneal for the formation thereof. The interconnect barrier layer 132 may prevent the diffusion of copper from the interconnect 130 and/or the copper-containing seed layer 122 into surrounding materials. In another embodiment, the alloy metal (e.g. the non-copper metal) within the copper-containing seed layer 122 may be used to tune and improve electromigration performance and/or may be of a sufficient concentration to prevent copper diffusion.

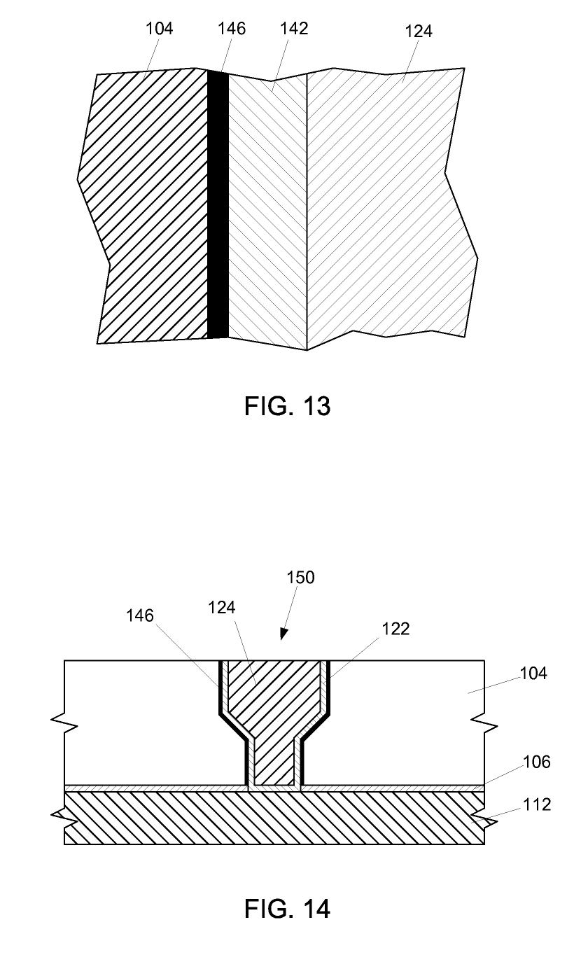

In an embodiment of the present description, an interconnect barrier layer may be self-formed, as illustrated in FIG. 8-13. Beginning with FIG. 1, a liner material layer 142, such as ruthenium, may be deposited to abut the dielectric material layer 104 and the exposed substrate portion 108, as shown in FIG. 8. The copper-containing seed layer 122, formed from the unstable organocopper alloy intermediate as described above, may be deposited over the liner material layer 142, as shown in FIG. 9. As shown in FIG. 10, the opening 102 may be filled with a conductive material 124, such as copper or an alloy thereof. As shown in FIG. 11, a portion of the conductive material 124 overlying the dielectric material layer 104 may be removed to form the interconnect 150. The interconnect 150 may be annealed (heated). This annealing results in the migration of the alloy metal 144 in the copper-containing seed layer 122 toward the dielectric layer 104 (shown by arrow 152) through the liner material layer 142, as shown in FIG. 12. The alloy metal 144 forms an interconnect barrier layer 146 between the liner material layer 142 and the dielectric material layer 104 while leaving the copper on the opposing side of the liner material layer 142 (shown as subsumed by the conductive material of the interconnect 150), as shown in FIGS. 13 and 14. In one embodiment, the alloy metal 144 is manganese. It is understood that the copper-containing seed layer 122 may be annealed to form the interconnect barrier layer 146 prior to the opening 102 being filled with the conductive material 124 to form the interconnect 150 (see FIG. 9).

It is also understood that the subject matter of the present description is not necessarily limited to specific applications illustrated in FIGS. 1-14. The subject matter may be applied to other stacked die applications. Furthermore, the subject matter may also be used in any appropriate application outside of the microelectronic device fabrication field.

The detailed description has described various embodiments of the devices and/or processes through the use of illustrations, block diagrams, flowcharts, and/or examples. Insofar as such illustrations, block diagrams, flowcharts, and/or examples contain one or more functions and/or operations, it will be understood by those skilled in the art that each function and/or operation within each illustration, block diagram, flowchart, and/or example can be implemented, individually and/or collectively, by a wide range of hardware, software, firmware, or virtually any combination thereof.

The described subject matter sometimes illustrates different components contained within, or connected with, different other components. It is understood that such illustrations are merely exemplary, and that many alternate structures can be implemented to achieve the same functionality. In a conceptual sense, any arrangement of components to achieve the same functionality is effectively “associated” such that the desired functionality is achieved. Thus, any two components herein combined to achieve a particular functionality can be seen as “associated with” each other such that the desired functionality is achieved, irrespective of structures or intermediate components. Likewise, any two components so associated can also be viewed as being “operably connected”, or “operably coupled”, to each other to achieve the desired functionality, and any two components capable of being so associated can also be viewed as being “operably couplable”, to each other to achieve the desired functionality. Specific examples of operably couplable include but are not limited to physically mateable and/or physically interacting components and/or wirelessly interactable and/or wirelessly interacting components and/or logically interacting and/or logically interactable components.

It will be understood by those skilled in the art that terms used herein, and especially in the appended claims are generally intended as “open” terms. In general, the terms “including” or “includes” should be interpreted as “including but not limited to” or “includes but is not limited to”, respectively. Additionally, the term “having” should be interpreted as “having at least”.

The use of plural and/or singular terms within the detailed description can be translated from the plural to the singular and/or from the singular to the plural as is appropriate to the context and/or the application.

It will be further understood by those skilled in the art that if an indication of the number of elements is used in a claim, the intent for the claim to be so limited will be explicitly recited in the claim, and in the absence of such recitation no such intent is present. Additionally, if a specific number of an introduced claim recitation is explicitly recited, those skilled in the art will recognize that such recitation should typically be interpreted to mean “at least” the recited number.

The use of the terms “an embodiment,” “one embodiment,” “some embodiments,” “another embodiment,” or “other embodiments” in the specification may mean that a particular feature, structure, or characteristic described in connection with one or more embodiments may be included in at least some embodiments, but not necessarily in all embodiments. The various uses of the terms “an embodiment,” “one embodiment,” “another embodiment,” or “other embodiments” in the detailed description are not necessarily all referring to the same embodiments.

While certain exemplary techniques have been described and shown herein using various methods and systems, it should be understood by those skilled in the art that various other modifications may be made, and equivalents may be substituted, without departing from claimed subject matter or spirit thereof. Additionally, many modifications may be made to adapt a particular situation to the teachings of claimed subject matter without departing from the central concept described herein. Therefore, it is intended that claimed subject matter not be limited to the particular examples disclosed, but that such claimed subject matter also may include all implementations falling within the scope of the appended claims, and equivalents thereof.

What is claimed is:

1. A method for fabricating an interconnection comprising:
chemisorbing a copper pre-cursor on an opening formed in a dielectric material;
exposing the copper pre-cursor to an organometallic co-reagent to form an unstable copper intermediate; and
forming a copper-containing seed layer through the spontaneous reductive elimination of organic by-products from the unstable copper intermediate.

2. The method of claim 1, wherein forming a copper pre-cursor comprises forming a copper pre-cursor selected from the group consisting of a homoleptic copper(I) compound, a heteroleptic copper(I) compound, a homoleptic copper(II) compound, and a heteroleptic copper(II) compound.

3. The method of claim 2, wherein forming a copper pre-cursor comprises forming a bis(dimethylamino-2-propoxide)copper(II) pre-cursor.

4. The method of claim 1, wherein exposing the copper pre-cursor to an organometallic co-reagent comprises exposing the copper pre-cursor to an organometallic co-reagent selected from the group consisting of homoleptic organomanganese compounds, homoleptic organoaluminum compounds, homoleptic organomagnesium compounds, homoleptic organozinc compounds, homoleptic organotin compounds compounds, heteroleptic organomanganese compounds, heteroleptic organoaluminum compounds, heteroleptic organomagnesium compounds, heteroleptic organozinc compounds, and heteroleptic organotin compounds.

5. The method of claim 4, wherein exposing the copper pre-cursor to an organometallic co-reagent comprises exposing the copper pre-cursor to a triethylaluminum organometallic co-reagent.

6. The method of claim 1, wherein forming a copper-containing seed layer comprises forming a copper alloy seed layer.

7. The method of claim 1, wherein chemoisorbing of the copper pre-cursor, exposing the copper pre-cursor to an organometallic co-reagent, and forming a copper-containing seed layer is repeated in the same sequence one or more cycles.

8. The method of claim 7, wherein chemisorbing of the copper pre-cursor, exposing the copper pre-cursor to an organometallic co-reagent, and forming a copper-containing seed layer is repeated in the same sequence one or more cycles with a different copper pre-cursor and/or a different organometallic co-reagent.

9. The method of claim 1, wherein chemisorbing of the copper pre-cursor, exposing the copper pre-cursor to an organometallic co-reagent, and forming a copper-containing seed layer is performed at a temperature between about 20° C. and 150° C.

10. The method of claim 1, further comprising filling the opening with a conductive material.

11. A method for fabricating an interconnection comprising:
forming a liner layer on an opening formed in a dielectric material;
chemisorbing a copper pre-cursor on the liner layer;
exposing the copper pre-cursor to an organometallic co-reagent to form an unstable copper intermediate;
forming a copper alloy seed layer through the spontaneous reductive elimination of organic by-products from the unstable copper intermediate; and
annealing the copper seed layer to migrate alloy metal within the copper alloy through the liner layer to form a barrier between the dielectric material and liner layer.

12. The method of claim 11, wherein the liner layer comprises ruthenium.

13. The method of claim 11, wherein forming the copper alloy seed layer comprises forming a copper manganese seed layer.

14. The method of claim 11, wherein forming a copper pre-cursor comprises forming a copper pre-cursor selected from the group consisting of a homoleptic copper(I) compound, a heteroleptic copper(I) compound, a homoleptic copper(II) compound, and a heteroleptic copper(II) compound.

15. The method of claim 14, wherein forming a copper pre-cursor comprises forming a bis(dimethylamino-2-propoxide)copper(II) pre-cursor.

16. The method of claim 11, wherein exposing the copper pre-cursor to an organometallic co-reagent comprises exposing the copper pre-cursor to an organometallic co-reagent selected from the group consisting of homoleptic organomanganese compounds, homoleptic organoaluminum compounds, homoleptic organomagnesium compounds, homoleptic organozinc compounds, homoleptic organotin compounds compounds, heteroleptic organomanganese compounds, heteroleptic organoaluminum compounds, heteroleptic organomagnesium compounds, heteroleptic organozinc compounds, and heteroleptic organotin compounds.

17. The method of claim 16, wherein exposing the copper pre-cursor to an organometallic co-reagent comprises exposing the copper pre-cursor to a triethylaluminum organometallic co-reagent.

18. The method of claim 11, wherein chemisorbing of the copper pre-cursor, exposing the copper pre-cursor to an organometallic co-reagent, and forming a copper-containing seed layer is performed at a temperature between about 20° C. and 150° C.

19. The method of claim 11, further comprising filling the opening with a conductive material.

20. The method of claim 11, wherein the dielectric material is selected from the group consisting of silicon dioxide, carbon-doped silicon dioxides, polymer-based materials, and low-k dielectrics.
